(19) United States
(12) Patent Application Publication
(10) Pub. No.: US 2026/0005121 A1
(43) Pub. Date: Jan. 1, 2026

(54) DISPLAY DEVICE

(71) Applicant: SAMSUNG DISPLAY CO., LTD., YONGIN-SI (KR)

(72) Inventors: Hyong Do CHOI, Yongin-si (KR); Seung Hee LEE, Yongin-si (KR)

(21) Appl. No.: 19/062,824

(22) Filed: Feb. 25, 2025

(30) Foreign Application Priority Data
Jul. 1, 2024 (KR) 10-2024-0086217

(51) Int. Cl. H01L 23/498; H10K 59/131; H10K 59/95

(52) U.S. Cl. CPC H01L 23/49838; H10K 59/131; H10K 59/95

(57) ABSTRACT

A display device includes a display panel. A first circuit board is connected to the display panel. A second circuit board is connected to the first circuit board. A first pad is in a first pad area of the second circuit board. A first terminal is in a first terminal area of the first circuit board and overlaps with the first pad. The first pad includes first sub-pads in a first row of the first pad area and spaced apart from each other in a first direction. A second sub-pad is in a second row of the first pad area. The first terminal comprises first sub-terminals overlapping with the first sub-pads and a second sub-terminal overlapping with the second sub-pad. The second sub-terminal is between adjacent first sub-pads and extends longitudinally in a second direction to overlap with the second sub-pad.

This application claims priority under 35 U.S.C. § 119 to Korean Patent Application No. 10-2024-0086217, filed on Jul. 1, 2024 in the Korean Intellectual Property Office, the disclosure of which is incorporated by reference in its entirety herein.

### 1. TECHNICAL FIELD

The present disclosure relates to a display device, and more particularly, to a display device in which the pitch of pads and the number of pads can be increased in a given area.

### 2. DISCUSSION OF RELATED ART

An organic light-emitting diode display, unlike a liquid-crystal display, is self-luminous. Accordingly, an organic light-emitting diode display does not require a separate light source for displaying images. Therefore, the organic light-emitting diode display can be manufactured to be lighter and thinner than other display devices, such as liquid-crystal displays. In addition, an organic light-emitting diode display has high-quality characteristics, such as low power consumption, high luminance and fast response speed. Accordingly, the organic light-emitting diode display is attracting attention as a next generation display.

### SUMMARY

Aspects of embodiments of the present disclosure provide a display device in which the pitch of pads and the number of pads can be increased in a given area.

According to an embodiment of the present disclosure, a display device includes a display panel. A first circuit board is connected to the display panel. A second circuit board is connected to the first circuit board. A first pad is disposed in a first pad area of the second circuit board. A first terminal is disposed in a first terminal area of the first circuit board. The first terminal overlaps with the first pad in a plan view. The first pad comprises first sub-pads disposed in a first row of the first pad area and spaced apart from each other in a first direction and a second sub-pad disposed in a second row of the first pad area. The first terminal comprises first sub-terminals overlapping with the first sub-pads in the plan view and a second sub-terminal overlapping with the second sub-pad in the plan view. The second sub-terminal is disposed between first sub-pads adjacent to each other in the first direction and extends longitudinally in a second direction intersecting the first direction to overlap with the second sub-pad in the plan view.

In an embodiment, the first sub-pads and the second sub-pad may extend longitudinally in different directions from each other.

In an embodiment, the first sub-pad may extend longitudinally in the second direction, and the second sub-pad may be extend longitudinally in the first direction.

In an embodiment, the first sub-terminal may include a first pattern portion and a second pattern portion having different widths in the first direction from each other.

In an embodiment, the width of the first pattern portion in the first direction may be greater than the width of the second pattern portion in the first direction.

In an embodiment, the second pattern portion may protrude from an upper side of the first pattern portion in the second direction.

In an embodiment, the first sub-terminals may be disposed in the first terminal area and overlap with the first row of the first pad area in the plan view, and the second sub-terminal may be disposed in the first terminal area and overlap with the first row and the second row of the first pad area in the plan view.

In an embodiment, a width of the first sub-terminals in the first direction may be greater than a width of the first sub-pads in the first direction.

In an embodiment, a width of the second sub-pad in the first direction may be greater than a width of the second sub-pad in the first direction.

In an embodiment, the display device may further include a second pad disposed in a second pad area of the display panel. A second terminal is disposed in a second terminal area of the first circuit board. The second terminal overlaps with the second pad in the plan view.

In an embodiment, the second pad may include a third sub-pad disposed in a first row of the second pad area, and a fourth sub-pad disposed in a second row of the second pad area.

In an embodiment, the second terminal may include third sub-terminals overlapping with the third sub-pad and spaced apart from each other in the first direction and a fourth sub-terminal overlapping with the fourth sub-pad, and the fourth sub-terminal may be disposed between third sub-pads adjacent to each other in the first direction and may extend longitudinally in the second direction to overlap with the fourth sub-pad in the plan view.

According to an embodiment of the present disclosure, a display device includes a display panel. A first circuit board is connected to the display panel. A second circuit board is connected to the first circuit board. A first pad is disposed in a first pad area of the display panel. A first terminal is disposed in a first terminal area of the first circuit board. The first terminal overlaps with the first pad in a plan view. The first pad comprises first sub-pads disposed in a first row of the first pad area and spaced apart from each other in a first direction and a second sub-pad disposed in a second row of the first pad area. The first terminal comprises first sub-terminals overlapping with the first sub-pads in the plan view and a second sub-terminal overlapping with the second sub-pad in the plan view. The second sub-terminal is disposed between first sub-pads adjacent to each other in the first direction and extends longitudinally in a second direction intersecting the first direction to overlap with the second sub-pad in the plan view.

According to an embodiment of the present disclosure, an electronic device includes a display device. A power supply provides power to the display device. The display device includes a display panel. A first circuit board is connected to the display panel. A second circuit board is connected to the first circuit board. A first pad is disposed in a first pad area of the second circuit board. A first terminal is disposed in a first terminal area of the first circuit board. The first terminal overlaps with the first pad in a plan view. The first pad comprises first sub-pads disposed in a first row of the first pad area and spaced apart from each other in a first direction and second sub-pads disposed in a second row of the first pad area and spaced apart from each other in the first direction. The first terminal comprises first sub-terminals overlapping with the first sub-pads in the plan view and second sub-terminals overlapping with the second sub-pads in the plan view. Each of the second sub-terminals is disposed between adjacent first sub-pads that are adjacent to each other in the first direction and extend longitudinally in a second direction intersecting the first direction to overlap with one second sub-pad of the second sub-pads in the plan view.

The details of one or more embodiments of the subject matter described in this specification are set forth in the accompanying drawings and the description below.

According to an embodiment of the present disclosure, the pitch of pads and the number of pads can be increased in a given area of a display device.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a plan view showing a display device according to an embodiment of the present disclosure.

FIG. 2 is an enlarged view of area A1 of FIG. 1 for illustrating pads of the control circuit board of FIG. 1 according to an embodiment of the present disclosure.

FIG. 3 is a view showing some of a plurality of pads of the control circuit board of FIG. 2 according to an embodiment of the present disclosure.

FIG. 4 is an enlarged view of area A1 of FIG. 1 for illustrating the terminals of the first connection circuit board of FIG. 1 according to an embodiment of the present disclosure.

FIG. 5 is a plan view showing some of the plurality of terminals of the first connection circuit board of FIG. 4 according to an embodiment of the present disclosure.

FIG. 6 is a plan view showing the first pads of FIG. 3 connected to the first terminals of FIG. 5 according to an embodiment of the present disclosure.

FIG. 7 is a plan view for illustrating how overlapping areas between a first pad and a first terminal change when the first terminal is shifted in the first opposite direction and the second direction relative to the first pad according to an embodiment of the present disclosure.

FIG. 8 is a plan view for illustrating how overlapping areas between a first pad and a first terminal change when the first terminal is shifted in the first opposite direction and the second opposite direction relative to the first pad according to an embodiment of the present disclosure.

FIG. 9 is a plan view for illustrating how overlapping areas between a first pad and a first terminal change when the first terminal is shifted in the first direction and the second direction relative to the first pad according to an embodiment of the present disclosure.

FIG. 10 is a plan view for illustrating how overlapping areas between a first pad and a first terminal change when the first terminal is shifted in the first direction and the second opposite direction relative to the first pad according to an embodiment of the present disclosure.

FIG. 11 is an enlarged view of area A1 of FIG. 1 for illustrating the pads of the display panel of FIG. 1 according to an embodiment of the present disclosure.

FIG. 12 is an enlarged view of area A1 of FIG. 1 for illustrating other terminals of the first connection circuit board of FIG. 1 according to an embodiment of the present disclosure.

FIG. 13 is a block diagram of an electronic device according to one embodiment.

FIGS. 14, 15 and 16 are schematic diagrams of electronic devices according to various embodiments.

### DETAILED DESCRIPTION OF EMBODIMENTS

The present invention will now be described more fully hereinafter with reference to the accompanying drawings, in which non-limiting embodiments of the present disclosure are shown. This invention may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification. In the attached figures, the thickness of layers and regions may be exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described in detail with reference to the accompanying drawings.

The present disclosure is a display device that includes a display panel having a connection circuit board connected to a control circuit board. The control circuit board has first sub-pads and second sub-pads in a pad area that overlap first sub-terminals and second sub-terminals of the connection circuit board for electrical connection therewith.

The first sub-pads and the second sub-pads are arranged in different rows from each other so that a first pitch between adjacent first sub-pads and a second pitch between adjacent second sub-pads can increase. Additionally, the number of the pads can increase due to the arrangement of the sub-pads in different rows.

The first sub-terminal is larger than the first sub-pad in a first direction, and the second sub-pad is larger than the second sub-terminal in the first direction. Therefore, even if either of the first pad or the first terminal is shifted and are misaligned with respect to each other, at least a portion of the first sub-pad and at least a portion of the first sub-terminal can overlap each other to maintain electrical connection therebetween. Therefore, the display panel may have increased stability and malfunctions based on electrical disconnection due to misalignment can be prevented.

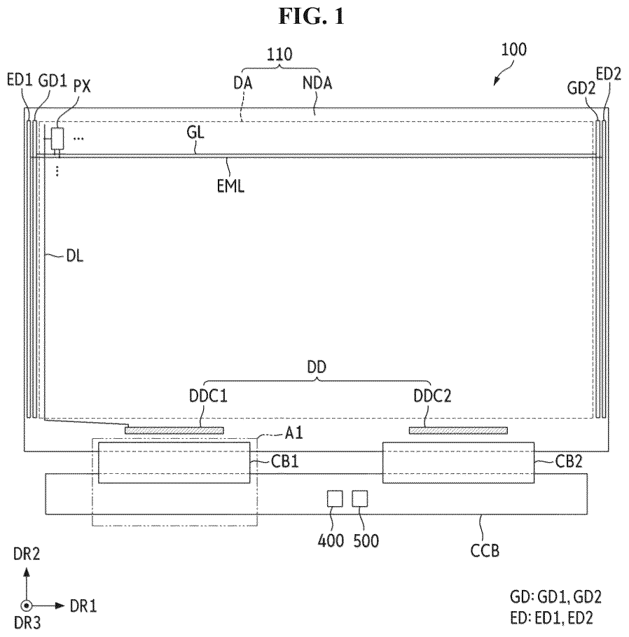

FIG. 1 is a plan view showing a display device 100 according to an embodiment of the present disclosure.

Referring to FIG. 1, a display device 100 is for displaying at least one moving image and/or still image. In an embodiment, the display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things. However, those listed-above are merely as examples, and the display device 100 may be employed in other electronic devices as well, including various different small-sized, medium-sized or large-sized electronic devices. According to an embodiment of the present disclosure, the electronic device may include a display device and a power supply configured to provide power to the display device.

In an embodiment, the display device 100 may be a light-emitting display device such as an organic light-emitting display device including organic light-emitting diodes, a quantum-dot light-emitting display device including a quantum-dot light-emitting layer, and an ultra-small light-emitting display device including an ultra-small light-emitting diodes such as micro or nano light-emitting diodes (micro LEDs or nano LEDs). It should be understood, however, embodiments of the present disclosure are not necessarily limited thereto. For example, the display device 100 may be other types of display devices than light-emitting display devices. In the following descriptions, a light-emitting display device (e.g., an organic light-emitting display device) is disclosed as the display device 100.

In an embodiment, the display device 100 may include a display panel 110, and a gate driver GD, an emission driver ED and a data driver DD that provide driving signals to pixels PX of the display panel 110. The pixels PX may be arranged in a display area of the display panel 110. The gate driver GD and the emission driver ED may be disposed in a non-display area NDA of the display panel 110. In an embodiment, the non-display area NDA may at least partially surround the display area DA (e.g., in a plan view). The data driver DD may be connected to the non-display area NDA of the display panel 110 through first circuit boards CB1 and CB2 (hereinafter referred to as connection circuit boards).

In an embodiment, the display device 100 may further include a power supply unit 400 and a timing controller 500 arranged on a second circuit board (hereinafter referred to as a control circuit board CCB). The power supply unit 400 may apply supply voltages to the pixels PX, the gate driver GD, the emission driver ED, and the data driver DD. The timing controller 500 may control the operations of a first gate driver GD1 and a second gate driver GD2 of the gate driver GD, a first emission driver ED1 and a second emission driver ED2 of the emission driver ED, and the data driver DD.

In an embodiment, the display panel 110 may have a rectangular shape when viewed from the top (e.g., in a plan view). Although the display panel 110 has the horizontal length (e.g., the length in the first direction DR1) larger than the vertical length (e.g., the length in the second direction DR2) in an embodiment shown in FIG. 1, the shape of the display panel 110 is not necessarily limited thereto. For example, the display panel 110 may have a shape (e.g., in a plan view) in which the vertical length is larger than the horizontal length, or may have a square shape, etc. In some embodiments, the display panel 110 may include rounded corners.

The display panel 110 may be a rigid display panel that is not substantially deformed, or a flexible display panel that can be deformed, such as at least partially folded, bent or rolled. In some embodiments, the display panel 110 may be provided to the display device 100 without being bent or in a partially bent orientation.

The display panel 110 may include a display area DA and a non-display area NDA. In some embodiments, the display panel 110 may include a plurality of display areas DA and/or non-display areas NDA.

A plurality of pixels PX may be disposed in the display area DA. A plurality of pixels PX can display images. The plurality of pixels SP may be connected to gate lines GL, emission control lines EML, data lines DL and voltage lines VL. In an embodiment, the gate lines GL and the emission control lines EML may extend longitudinally in the first direction DR1, and the data lines DL may extend longitudinally in the second direction DR2. The first direction DR1 may be the horizontal direction, the second direction DR2 may be the vertical direction, and the first direction DR1 and the second direction DR2 may be perpendicular each other. However, embodiments of the present disclosure are not necessarily limited thereto and the first and second directions DR1, DR2 may cross each other (e.g., intersect) at various different angles.

The non-display area NDA may be disposed around the display area DA. According to an embodiment of the present disclosure, the non-display area NDA may surround the display area DA (e.g., in a plan view).

The display area DA may have a variety of shapes according to embodiments. For example, the display area DA may have a rectangular shape, a non-rectangular polygonal shape, a circular shape, an elliptical shape, an irregular shape, or other shapes (e.g., in a plan view). According to an embodiment of the present disclosure, the display area DA may have a shape that conforms to the shape of the display panel 110.

The gate driver GE and the emission driver ED may be disposed in the non-display area NDA. For example, in an embodiment the gate driver GD may include the first gate driver GD1 and the second gate driver GD2, and the emission driver ED may include the first emission driver ED1 and the second emission driver ED2. Therefore, the first gate driver GD1 and the first emission driver ED1 may be arranged in the non-display area NDA (e.g., a left non-display area) located on the left side of the display area DA in the direction opposite to the first direction DR1, and the second gate driver GD2 and the second emission driver ED2 may be arranged in the non-display area NDA (e.g., a right non-display area) located on the right side of the display area DA in the first direction DR1. However, embodiments of the present disclosure are not necessarily limited thereto.

The gate driver GD may drive the gate lines GL. For example, the first gate driver GD1 and the second gate driver GD2 may provide gate signals to the gate lines GL. The gate lines GL may be connected to the first gate driver GD1 and the second gate driver GD2. For example, one side of each of the gate lines GL may be electrically connected to the first gate driver GD1, and the opposite side of each of the gate lines GL may be electrically connected to the second gate driver GD2.

The emission driver ED can drive the emission control lines EML. For example, the first emission driver ED1 and the second emission driver ED2 may provide emission control signals to the emission control lines EML. The emission control lines EML may be connected to the first emission driver ED1 and the second emission driver ED2. For example, in an embodiment one side of each of the emission control lines EML may be electrically connected to the first emission driver ED1, and the opposite side of each of the emission control lines EML may be electrically connected to the second emission driver ED2.

In an embodiment, the connection circuit boards CB1 and CB2 may include a first connection circuit board CB1 and a second connection circuit board CB2. However, embodiments of the present disclosure are not necessarily limited thereto and the number of the connection circuit boards may be more than two in some embodiments.

The connection circuit boards CB1 and CB2 may be connected to the display panel 110 and the control circuit board CCB. For example, as shown in FIG. 1, the first connection circuit board CB1 may be connected to the display panel 110 and the control circuit board CCB, and the second connection circuit board CB2 may be connected to the display panel 110 and the control circuit board CCB. In an embodiment, the connection circuit boards CB1 and CB2 may be, but is not necessarily limited to, a flexible printed circuit board (FPCB), a printed circuit board (PCB) or a flexible film such as chip on film (COF).

The timing controller and the power supply unit may be disposed on the control circuit board CCB. In an embodiment, the control circuit board CCB may be, but is not necessarily limited to, a flexible printed circuit board (FPCB), a printed circuit board (PCB) or a flexible film such as chip on film (COF). Although there is one control circuit board CCB shown in an embodiment of FIG. 1, embodiments of the present disclosure are not necessarily limited thereto and the number of the control circuit boards may be two or more in some embodiments.

In an embodiment, the data driver DD may include a plurality of driver circuits DDC1 and DDC2 (hereinafter referred to as data driver circuits) arranged in the first direction DR1 in the non-display area of the display panel 110. For example, in an embodiment the data driver DD may include a first data driver circuit DDC1 and a second data driver DDC2 mounted in the non-display area of the display panel 110. Each of the data driver circuits DDC1 and DDC2 may include, for example, an integrated circuit.

A plurality of data lines DL may be connected to the data driver DD. For example, the plurality of data lines DL may be separately connected to the plurality of data driver circuits DDC1 and DDC2. For example, in an embodiment the plurality of data lines DL may include a plurality of first data lines connected to the first data driver circuit DDC1 and a plurality of second data lines connected to the second data driver circuit DDC2.

Through the first connection circuit board CB1, a gate timing control signal, an emission timing control signal, a gate clock signal, an emission clock signal, a gate start signal, an emission start signal, a high-level voltage, and a low-level voltage from the timing controller may be provided to the first gate driver GD1 and the first emission driver ED1. For example, the gate timing control signal, the gate clock signal, the gate start signal, the high-level voltage and the low-level voltage may be provided to the first gate driver GD1, and the emission timing control signal, the emission clock signal, the emission start signal, the high-level voltage and the low-level voltage may be provided to the first emission driver ED1. In addition, power signals from the power supply unit may be provided to the first gate driver GD1, the first emission driver ED1 and the pixels PX through the first connection circuit board CB1. In an embodiment, the power signals may include, for example, a supply voltage, a common voltage, an initialization voltage, and a bias voltage.

Through the second connection circuit board CB2, a gate timing control signal, an emission timing control signal, a gate clock signal, an emission clock signal, a high-level voltage and a low-level voltage from the timing controller may be provided to the second gate driver GD2 and the second emission driver ED2. For example, the gate timing control signal, the gate clock signal, the high-level voltage and the low-level voltage may be provided to the second gate driver GD2, and the emission timing control signal, the emission clock signal, the high-level voltage and the low-level voltage may be provided to the second emission driver ED2. In addition, power signals from the power supply unit may be provided to the second gate driver GD2, the second emission driver ED2 and the pixels PX through the second connection circuit board CB2.

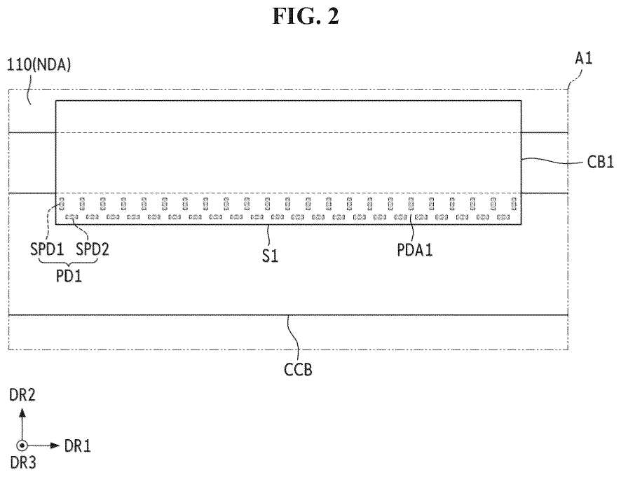

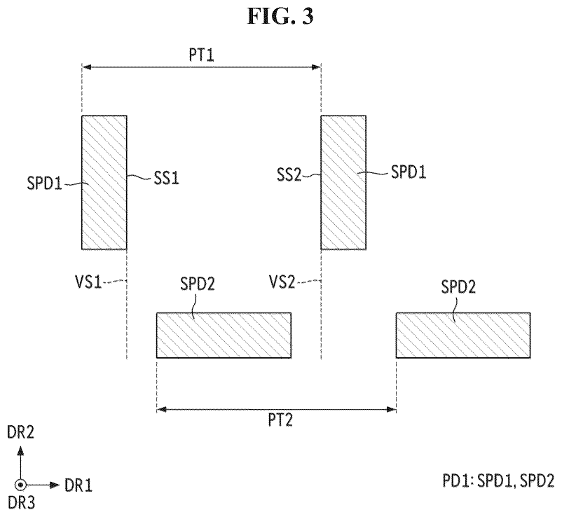

FIG. 2 is an enlarged view of area A1 of FIG. 1 for illustrating pads of the control circuit board CCB of FIG. 1. FIG. 3 is a view showing some of a plurality of pads of the control circuit board CCB of FIG. 2.

As shown in FIGS. 2 and 3, the control circuit board CCB may include a plurality of pads (hereinafter referred to as first pads PD1). The plurality of first pads PD1 may be arranged in a pad area (hereinafter referred to as a first pad area PDA1) of the control circuit board CCB. When viewed from the top (e.g., in a plan view), the first pad area PDA1 may include, for example, an area where the first connection circuit board CB1 and the control circuit board CCB overlap each other. In an embodiment, the first pad area PDA1 may be on an upper side of the control circuit board CCB (e.g., in the second direction DR2).

A plurality of first pads PD1 of the control circuit board CCB may be connected to one side of the first connection circuit board CB1, such as a lower side of the first connection circuit board CB1 in a direction opposite to the second direction DR2.

In an embodiment, the plurality of first pads PD1 of the control circuit board CCB may include first sub-pads SPD1 and second sub-pads SPD2 arranged in different rows in the first pad area PDA1, such as a first row and a second row, respectively. The first row and the second row may be arranged along the second direction DR2.

The first sub-pads SPD1 may be arranged in the first row of the first pad area PDA1 in the first direction DR1. In an embodiment, the first sub-pads SPD1 may be equally spaced apart from one another (e.g., along the first direction DR1). For example, the spacing between two first sub-pads SPD1 adjacent to each other in the first direction DR1 may be equal to the spacing between other two first sub-pads SPD1 adjacent to each other in the first direction DR1. For example, as shown in FIG. 2, a pitch PT1 (e.g., a period; hereinafter referred to as a first pitch PT1) of the first sub-pads SPD1 equally spaced apart from one another in the first direction DR1 may be constant. For example, in an embodiment the first pitch PT1 of the first sub-pads SPD1 may be in a range from about 200 μm to about 300 μm. For example, the first pitch PT1 may be about 260 μm.

In an embodiment, each of the first sub-pads SPD1 may extend longitudinally in the second direction DR2. For example, the first sub-pads SPD1 may extend longitudinally in a direction (e.g., the second direction DR2) that is perpendicular to the arrangement direction of the first sub-pads SPD1 (e.g., the first direction DR1). In an embodiment, the length of the vertical sides of the first sub-pads SPD1 (e.g., the sides parallel to the second direction DR2) may be greater than the length of the horizontal sides of the first sub-pads SPD1 (e.g., the sides parallel to the first direction DR1). As described above, in an embodiment the first sub-pads SPD1 may have a rectangular shape having longer sides in the second direction DR2 than in the first direction DR1.

The second sub-pads SPD2 may be arranged in the second row of the first pad area PDA1 in the first direction DR1. In an embodiment, the second sub-pads SPD2 may be equally spaced apart from one another (e.g., in the first direction DR1). For example, the spacing between two second sub-pads SPD2 adjacent to each other in the first direction DR1 may be equal to the spacing between other two second sub-pads SPD2 adjacent to each other in the second direction DR2. For example, as shown in FIG. 2, a pitch PT2 (e.g., a period; hereinafter referred to as a second pitch PT2) of the second sub-pads SPD2 equally spaced apart from one another in the first direction DR1 may be constant. For example, in an embodiment the second pitch PT2 of the second sub-pads SPD2 may be in a range from about 200 μm to about 300 μm. For example, the second pitch PT2 may be about 260 μm.

In the first pad area PDA1, the second sub-pads SPD2 may be disposed on the lower side of the first sub-pads SPD1 (e.g., in the direction opposite to the second direction DR2). For example, when viewed from the top, the second sub-pads SPD2 may be arranged in the first pad area PDA1 between the first sub-pads SPD1 and one side S1 of the first connection circuit board CB1 (e.g., in the second direction DR2).

In an embodiment, each of the second sub-pads SPD2 may extend longitudinally in the first direction DR1. For example, the second sub-pads SPD2 may extend longitudinally along the arrangement direction of the second sub-pads SPD2 (e.g., the first direction DR1). In an embodiment, the length of the horizontal sides of the second sub-pads SPD2 (e.g., the sides parallel to the first direction DR1) may be greater than the length of the vertical sides of the second sub-pads SPD2 (e.g., the sides parallel to the second direction DR2). As described above, in an embodiment the second sub-pads SPD2 may have a rectangular shape having longer sides in the first direction DR1 than in the second direction DR2. In an embodiment, the length of the longer sides of the second sub-pads SPD2 (e.g., the sides extending longitudinally in the first direction DR1) may be greater than the length of the longer sides of the first sub-pads SPD1 (e.g., the sides extending longitudinally in the second direction DR2). In addition, the length of the shorter sides of the second sub-pads SPD2 (e.g., the sides extending longitudinally in the second direction DR2) may be equal to the length of the shorter sides of the first sub-pads SPD1 (e.g., the sides extending longitudinally in the first direction DR1).

Each of the second sub-pads SPD2 may be disposed between every two first sub-pads SPD1 adjacent to each other in the first direction DR1. For example, as shown in FIG. 3, the sides of two first sub-pads SPD1 adjacent to each other in the first direction DR1 which face each other are defined as a first vertical side SS1 and a second vertical side SS2, respectively. The second sub-pads SPD2 may be arranged between a first virtual line VS1 (hereinafter referred to as a first virtual line) extending along the first vertical side SS1 and a second virtual line VS2 (hereinafter referred to as a second virtual line) extended along the second vertical side SS2. For example, a second sub-pad SPD2 may be disposed between the first virtual line VS1 and the second virtual line VS2 (e.g., in the first direction DR1) so that it does not overlap with the first vertical side SS1 or the second vertical side SS2 of the first sub-pads SPD1.

In an embodiment, as the first sub-pads SPD1 and the second sub-pads SPD2 are arranged in different rows, the first pitch PT1 and the second pitch PT2 can increase. In addition, as the first sub-pads SPD1 and the second sub-pads SPD2 are arranged in different rows, the number of first pads PD1 in the first pad area PDA1 can increase.

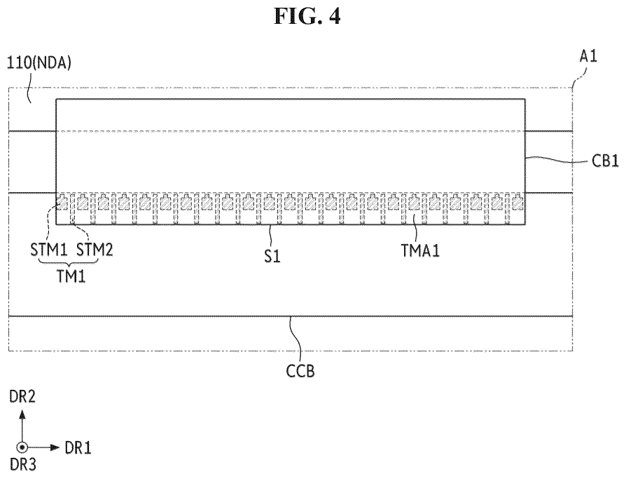

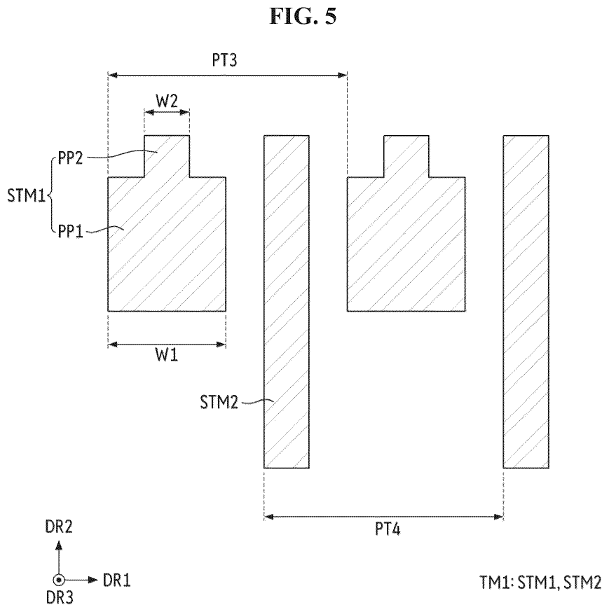

In an embodiment, the first pads PD1 of the control circuit board CCB described above may be connected to a plurality of terminals of the first connection circuit board CB1, which will be described in detail with reference to FIGS. 4 and 5 as follows.

FIG. 4 is an enlarged view of area A1 of FIG. 1 for illustrating the terminals of the first connection circuit board CB1 of FIG. 1. FIG. 5 is a view showing some of the plurality of terminals of the first connection circuit board CB1 of FIG. 4.

As shown in FIGS. 4 and 5, the first connection circuit board CB1 may include a plurality of terminals (hereinafter referred to as first terminals TM1). A plurality of first terminals TM1 may be disposed in a terminal area TMA1 (hereinafter referred to as a first terminal area TMA1) of the first connection circuit board CB1. In an embodiment, the first terminal area TMA1 may be disposed on a lower side of the first connection circuit board CB1 in a direction opposite to the second direction DR2. When viewed from the top, the first terminal area TMA1 may include, for example, an area where the first connection circuit board CB1 and the control circuit board CCB overlap each other.

The plurality of first terminals TM1 of the first connection circuit board CB1 may be connected to one side of the control circuit board CCB, such as an upper side of the control circuit board CCB in the second direction DR2. For example, the plurality of first terminals TM1 of the first connection circuit board CB1 may overlap (e.g., in a plan view) and be connected to the first pads PD1 of the control circuit board CCB, respectively. In an embodiment, the plurality of first terminals TM1 and the first pads PD1 may be electrically connected with each other directly or via connecting members such as conductive balls. Herein, the connection members may include conductive adhesive members such as an anisotropic conductive film.

In an embodiment, the plurality of first terminals TM1 of the first connection circuit board CB1 may include first sub-terminals STM1 and second sub-terminals STM2 having different shapes from each other arranged in the first terminal area TMA1.

In an embodiment, the first sub-terminals STM1 may be arranged in a row in the first direction DR1 in the first terminal area TMA1, such as in the first row. For example, the first sub-terminals STM1 may be arranged in the first terminal area TMA1 such that they overlap with the first sub-pads SPD1 described above, respectively (e.g., in a plan view). In an embodiment, the first sub-terminals STM1 may be equally spaced apart from one another. For example, the spacing between two first sub-terminals STM1 adjacent to each other in the first direction DR1 may be equal to the spacing between other two first sub-terminals STM1 adjacent to each other in the first direction DR1. For example, as shown in FIG. 4, a pitch PT3 (e.g., period; hereinafter referred to as a third pitch PT3) of the first sub-terminals STM1 equally spaced apart from one another in the first direction DR1 may be constant.

In an embodiment, each of the first sub-terminals STM1 may include a first pattern portion PP1 and a second pattern portion PP2 having different widths from each other. The second pattern portion PP2 may protrude from one side of the first pattern portion PP1. For example, in an embodiment the second pattern portion PP2 may protrude from the upper side (e.g., in the second direction DR2) of the first pattern portion PP1 and may protrude in the second direction DR2. In an embodiment, the second pattern portion PP2 may protrude from the center (e.g., in the first direction DR1) of the upper side. The width W1 of the first pattern portion PP1 (e.g., length in the first direction DR1) may be larger than the width W2 of the second pattern portion PP2 (e.g., length in the first direction DR1). For example, in an embodiment the width W1 of the first pattern portion PP1 may be three times the width W2 of the second pattern portion PP2. The third pitch PT3 of the first sub-terminals STM1 may be the third pitch PT3 of the first pattern portions PP1.

The first sub-terminals STM1 may be connected to the first sub-pads SPD1 described above, respectively. For example, the plurality of first sub-terminals STM1 and the first sub-pads SPD1 may be electrically connected with each other directly or via connection members such as conductive balls. In an embodiment, the connection members may include conductive adhesive members such as an anisotropic conductive film.

The second sub-terminals STM2 may be arranged in at least one row in the first direction DR1 in the first terminal area TMA1. For example, the second sub-terminals STM2 may be arranged in the first terminal area TMA1 such that they overlap (e.g., in a plan view) with the second sub-pads SPD2 described above, respectively. In an embodiment as shown in FIG. 4, the second sub-terminals STM2 may be arranged in both the first row and the second row. The second sub-terminals STM2 may be equally spaced apart from one another (e.g., in the first direction DR1). For example, the spacing between two second sub-terminals STM2 adjacent to each other in the first direction DR1 may be equal to the spacing between other two second sub-terminals STM2 adjacent to each other in the second direction DR2. In an embodiment, as shown in FIG. 5, a pitch PT4 (e.g., period; hereinafter referred to as a fourth pitch PT4) of the second sub-terminals STM2 equally spaced apart from one another in the first direction DR1 may be constant.

In the first terminal area TMA1, the second sub-terminals STM2 may be disposed between the first sub-terminals STM1 (e.g., in the first direction DR1). For example, when viewed from the top, each of the second sub-terminals STM2 may be disposed between every two first sub-terminals STM1 adjacent to each other in the first direction DR1 in the first terminal area TMA1.

Each of the second sub-terminals STM2 may extend longitudinally in the second direction DR2. For example, the second sub-terminals STM2 may extend longitudinally in a direction (e.g., the second direction DR2) that is perpendicular to the arrangement direction of the second sub-terminals STM2 (e.g., the first direction DR1). In an embodiment, the length of the vertical sides of the second sub-pads STM2 (e.g., the sides parallel to the second direction DR2) may be greater than the length of the horizontal sides of the second sub-terminals STM2 (e.g., the sides parallel to the first direction DR1). As described above, in an embodiment the second sub-terminals STM2 may have a rectangular shape having longer sides in the second direction DR2 than in the first direction DR1. In some embodiments, for the lengths in the second direction DR2, the length of the second sub-terminals STM2 may be larger than the length of the first sub-terminals STM1. For example, the first sub-terminals STM1 may have a length sufficient to overlap with the first row of the first pad area PDA1 described above, and the second sub-terminals STM2 may have a length sufficient to overlap with both the first row and the second row of the first pad area PDA1 described above. For example, the first sub-terminals STM1 may be arranged in the first terminal area TMA1 such that they overlap with the first row of the first pad area PDA1, and the second sub-terminals STM2 may be arranged in the first terminal area TMA1 such that they overlap with the first row and the second row of the first pad area PDA1. In an embodiment, the length of the first sub-terminals STM1 described above may be equal to the sum of the length of the first pattern portion PP1 and the length of the second pattern portion PP2.

The second sub-terminals STM2 may be connected to the second sub-pads SPD2 described above, respectively. For example, the plurality of second sub-terminals STM2 and the second sub-pads SPD2 may be electrically connected with each other directly or via connection members such as conductive balls. In an embodiment, the connection members may include conductive adhesive members such as an anisotropic conductive film.

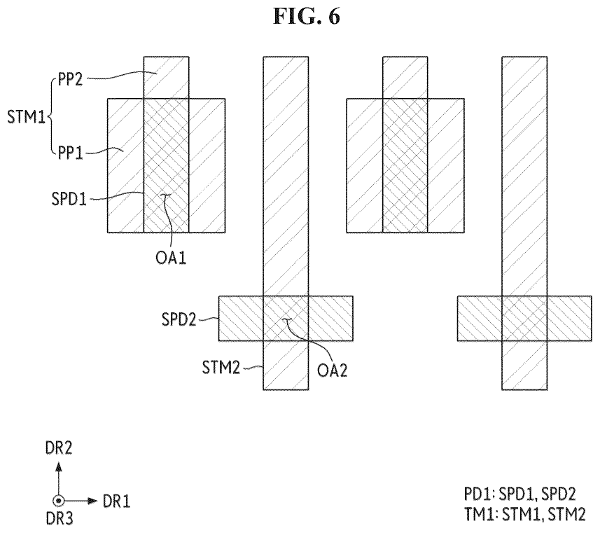

FIG. 6 is a view showing the first pads PD1 of FIG. 3 connected to the first terminals TM1 of FIG. 5.

As shown in FIG. 6, a first sub-terminal STM1 of a first terminal TM1 may be disposed on a first sub-pad SPD1 of a first pad PD1. The first sub-terminal STM1 may overlap with the first sub-pad SPD1 (e.g., in a plan view). The first sub-terminal STM1 and the first sub-pad SPD1 may be electrically connected to each other in a first overlapping area OA1 where the first sub-terminal STM1 and the first sub-pad SPD1 overlap each other (e.g., in a plan view). The first overlapping area OA1 may include, for example, an area defined by being surrounded by (e.g., in a plan view) the upper side of the first pattern portion PP1 included in the first sub-terminal STM1, the lower side of the first pattern portion PP1 included in the first sub-terminal STM1, the left side of the first sub-pad SPD1, and the right side of the first sub-pad SPD1.

A second sub-terminal STM2 of the first terminal TM1 may be disposed on a second sub-pad SPD2 of the first pad PD1. The second sub-terminal STM2 may overlap with the second sub-pad SPD2 (e.g., in a plan view). The second sub-terminal STM2 and the second sub-pad SPD2 may be electrically connected to each other in a second overlapping area OA2 where the second sub-terminal STM2 and the second sub-pad SPD2 overlap each other (e.g., in a plan view). The second overlapping area OA2 may include, for example, an area defined by being surrounded by the left side of the second sub-terminal STM2, the right side of the second sub-terminal STM2, the upper side of the second sub-pad SPD2 and the lower side of the second sub-pad SPD2.

When viewed from the top like FIG. 6, the second sub-terminal STM2 may be disposed between two first sub-pads SPD1 adjacent to each other in the first direction DR1. In addition, the second sub-terminal STM2 may overlap with the second sub-pad SPD2 (e.g., in a plan view). For example, when viewed from the top, the second sub-terminal STM2 may be disposed between two first sub-pads SPD1 adjacent to each other in the first direction DR1 and may overlap with the second sub-pad SPD2.

With respect to the first direction DR1 (e.g., the arrangement direction of the first sub-pads SPD1), the width of the first sub-terminal STM1 may be greater than the width of the first sub-pad SPD1. For example, the width W1 of the first pattern portion PP1 of the first sub-terminal STM1 may be greater than the width of the first sub-pad SPD1. In an embodiment the width W2 (e.g., length in the first direction DR1) of the second pattern portion PP2 of the first sub-terminal STM1 may be equal to the width (e.g., length in the first direction DR1) of the first sub-pad SPD1.

With respect to the first direction DR1 (e.g., the arrangement direction of the first sub-pads SPD1), the width of the second sub-pad SPD2 may be greater than the width of the second sub-terminal STM2.

As described above, since the first sub-terminal STM1 is larger than the first sub-pad SPD1 in the first direction DR1, and the second sub-pad SPD2 is larger than the second sub-terminal STM2 in the first direction DR1, even if either the first pad PD1 or the first terminal TM1 is shifted in the first direction DR1 or the opposite direction of the first direction DR1 (hereinafter referred to as the first opposite direction) and thus they are misaligned, at least a portion of the first sub-pad SPD1 and at least a portion of the first sub-terminal STM1 can overlap each other (e.g., in a plan view), and at least a portion of the second sub-pad SPD2 and at least a portion of the second sub-terminal STM2 can overlap each other (e.g., in a plan view). In other words, even if the pads and the terminals are misaligned in the first direction DR1 or the first opposite direction, the first sub-pad SPD1 and the first sub-terminal STM1 can be normally connected, and the second sub-pad SPD2 and the second sub-terminal STM2 can be normally connected.

In addition, with respect to the second direction DR2 (e.g., the direction perpendicular to the arrangement direction of the first sub-pads SPD1), the length of the first sub-terminal STM1 may be greater than the length of the first sub-pad SPD1. For example, the sum of the length of the first pattern portion PP1 of the first sub-terminal STM1 and the length of the second pattern portion PP2 of the first sub-terminal STM1 may be greater than the length of the first sub-pad SPD1. In an embodiment, the length of the first pattern portion PP1 of the first sub-terminal STM1 may be equal to the length of the first sub-pad SPD1.

With respect to the second direction DR2 (e.g., the direction perpendicular to the arrangement direction of the first sub-pads SPD1), the length of the second sub-terminal STM2 may be greater than the length of the second sub-pad SPD2.

As described above, since the first sub-pad SPD1 is larger than the first sub-terminal STM1 in the second direction DR2, and the second sub-terminal STM2 is larger than the second sub-pad SPD2 in the second direction DR2, even if either the first pad PD1 or the first terminal TM1 is shifted in the second direction DR2 or the opposite direction of the second direction DR2 (hereinafter referred to as the second opposite direction) and thus they are misaligned, at least a portion of the first sub-pad SPD1 and at least a portion of the first sub-terminal STM1 can overlap each other (e.g., in a plan view), and at least a portion of the second sub-pad SPD2 and at least a portion of the second sub-terminal STM2 can overlap each other (e.g., in a plan view). In other words, even if the pads and the terminals are misaligned in the second direction DR2 or the second opposite direction, the first sub-pad SPD1 and the first sub-terminal STM1 can be normally connected, and the second sub-pad SPD2 and the second sub-terminal STM2 can be normally connected.

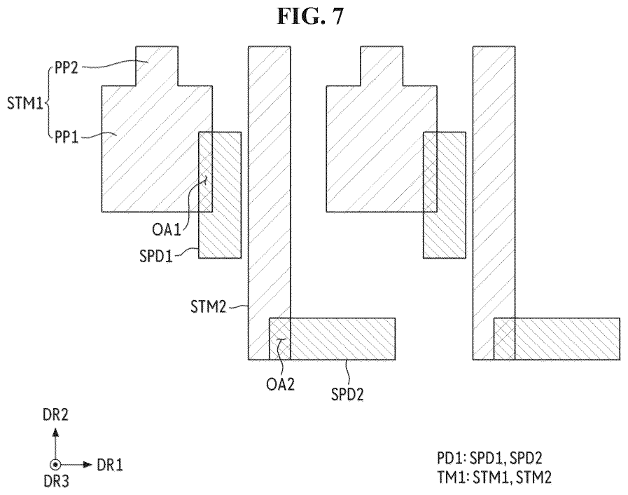

While FIG. 6 shows the first pad PD1 and the first terminal TM1 accurately aligned without misalignment, FIGS. 7, 8, 9 and 10 shows the first pad PD1 and the first terminal TM1 misaligned.

FIG. 7 is a plan view for illustrating how overlapping areas between a first pad PD1 and a first terminal TM1 change when the first terminal TM1 is shifted in the first opposite direction and the second direction DR2 relative to the first pad PD1.

When misalignment occurs in the process of connecting the first connection circuit board CB1 with the control circuit board CCB such that the first connection circuit board CB1 is moved by certain distances in the first opposite direction and the second direction DR2 as shown in FIG. 7, the first terminal TM1 may be shifted by a certain distance in the first opposite direction relative to the first pad PD1 and also shifted by a certain distance in the second direction DR2 relative to the first pad PD1.

When this happens, the area defined by being surrounded by the right side of the first pattern portion PP1 included in the first sub-terminal STM1, the lower side of the first pattern portion PP1 included in the first sub-terminal STM1, the left side of the first sub-pad SPD1, and the upper side of the first sub-pad SPD1 may be a first overlapping area OA1 between the first sub-terminal STM1 and the first sub-pad SPD1. In addition, the area defined by being surrounded by the right side of the second sub-terminal STM2, the lower side of the second sub-terminal STM2, the left side of the second sub-pad SPD2 and the upper side of the second sub-pad SPD2 may be a second overlapping area OA2 between the second sub-terminal STM2 and the second sub-pad SPD2.

In the first overlapping area OA1, the first sub-terminal STM1 and the first sub-pad SPD1 may be electrically connected to each other. In the second overlapping area OA2, the second sub-terminal STM2 and the second sub-pad SPD2 may be electrically connected to each other.

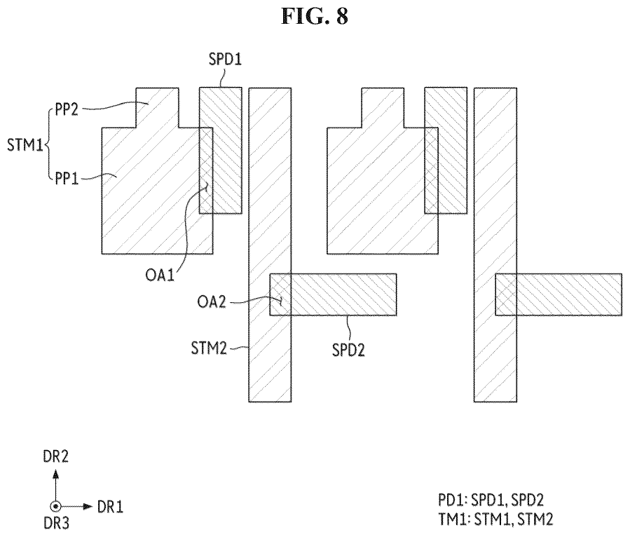

FIG. 8 is a plan view for illustrating how overlapping areas between a first pad PD1 and a first terminal TM1 change when the first terminal TM1 is shifted in the first opposite direction and the second opposite direction relative to the first pad PD1.

When misalignment occurs in the process of connecting the first connection circuit board CB1 with the control circuit board CCB such that the first connection circuit board CB1 is moved by certain distances in the first opposite direction and the second opposite direction as shown in FIG. 8, the first terminal TM1 may be shifted by a certain distance in the first opposite direction relative to the first pad PD1 and also shifted by a certain distance in the second opposite direction relative to the first pad PD1.

When this happens, the area defined by being surrounded by the right side of the first pattern portion PP1 included in the first sub-terminal STM1, the upper side of the first pattern portion PP1 included in the first sub-terminal STM1, the left side of the first sub-pad SPD1, and the lower side of the first sub-pad SPD1 may be a first overlapping area OA1 between the first sub-terminal STM1 and the first sub-pad SPD1. In addition, the area defined by being surrounded by the right side of the second sub-terminal STM2, the upper side of the second sub-pad SPD2, the left side of the second sub-pad SPD2 and the lower side of the second sub-pad SPD2 may be a second overlapping area OA2 between the second sub-terminal STM2 and the second sub-pad SPD2.

In the first overlapping area OA1, the first sub-terminal STM1 and the first sub-pad SPD1 may be electrically connected to each other. In the second overlapping area OA2, the second sub-terminal STM2 and the second sub-pad SPD2 may be electrically connected to each other.

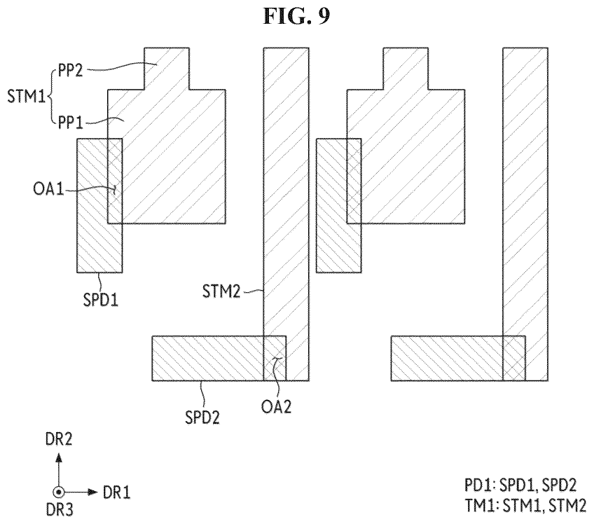

FIG. 9 is a plan view for illustrating how overlapping areas between a first pad PD1 and a first terminal TM1 change when the first terminal TM1 is shifted in the first direction DR1 and the second direction DR2 relative to the first pad PD1.

When misalignment occurs in the process of connecting the first connection circuit board CB1 with the control circuit board CCB such that the first connection circuit board CB1 is moved by certain distances in the first direction DR1 and the second direction DR2 as shown in FIG. 9, the first terminal TM1 may be shifted by a certain distance in the first direction DR1 relative to the first pad PD1 and also shifted by a certain distance in the second direction DR2 relative to the first pad PD1.

When this happens, the area defined by being surrounded by the left side of the first pattern portion PP1 included in the first sub-terminal STM1, the lower side of the first pattern portion PP1 included in the first sub-terminal STM1, the upper side of the first sub-pad SPD1, and the right side of the first sub-pad SPD1 may be a first overlapping area OA1 between the first sub-terminal STM1 and the first sub-pad SPD1. In addition, the area defined by being surrounded by the left side of the second sub-terminal STM2, the lower side of the second sub-pad SPD2, the upper side of the second sub-pad SPD2 and the right side of the second sub-pad SPD2 may be a second overlapping area OA2 between the second sub-terminal STM2 and the second sub-pad SPD2.

In the first overlapping area OA1, the first sub-terminal STM1 and the first sub-pad SPD1 may be electrically connected to each other. In the second overlapping area OA2, the second sub-terminal STM2 and the second sub-pad SPD2 may be electrically connected to each other.

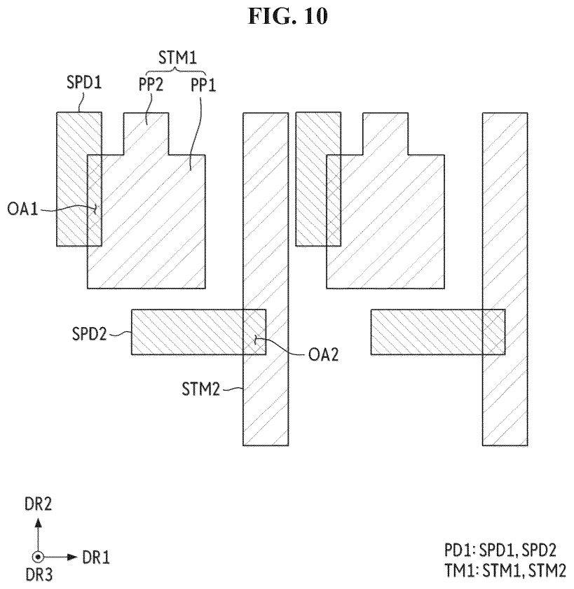

FIG. 10 is a plan view for illustrating how overlapping areas between a first pad PD1 and a first terminal TM1 change when the first terminal TM1 is shifted in the first direction DR1 and the second opposite direction relative to the first pad PD1.

When misalignment occurs in the process of connecting the first connection circuit board CB1 with the control circuit board CCB such that the first connection circuit board CB1 is moved by certain distances in the first direction DR1 and the second opposite direction as shown in FIG. 10, the first terminal TM1 may be shifted by a certain distance in the first direction DR1 relative to the first pad PD1 and also shifted by a certain distance in the second opposite direction relative to the first pad PD1.

When this happens, the area defined by being surrounded by the left side of the first pattern portion PP1 included in the first sub-terminal STM1, the upper side of the first pattern portion PP1 included in the first sub-terminal STM1, the right side of the first sub-pad SPD1, and the lower side of the first sub-pad SPD1 may be a first overlapping area OA1 between the first sub-terminal STM1 and the first sub-pad SPD1. In addition, the area defined by being surrounded by the left side of the second sub-terminal STM2, the upper side of the second sub-pad SPD2, the right side of the second sub-pad SPD2 and the lower side of the second sub-pad SPD2 may be a second overlapping area OA2 between the second sub-terminal STM2 and the second sub-pad SPD2.

In the first overlapping area OA1, the first sub-terminal STM1 and the first sub-pad SPD1 may be electrically connected to each other. In the second overlapping area OA2, the second sub-terminal STM2 and the second sub-pad SPD2 may be electrically connected to each other.

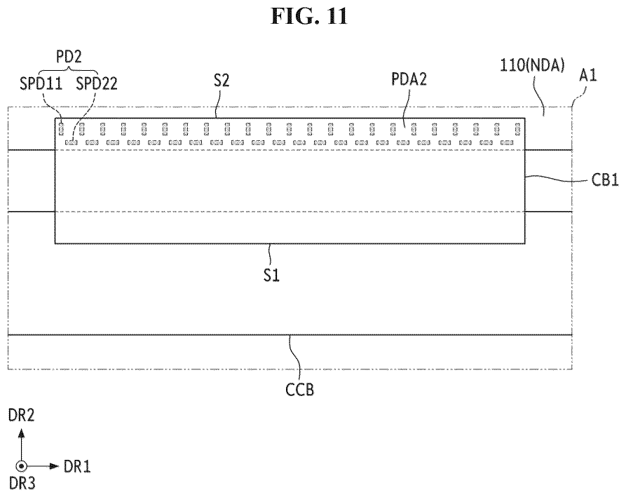

FIG. 11 is an enlarged view of area A1 of FIG. 1 for illustrating the pads of the display panel 110 of FIG. 1.

As shown in FIG. 11, the display panel 110 may include a plurality of pads PD2 (hereinafter referred to as second pads PD2). The plurality of second pads PD2 may be disposed in a pad area (hereinafter referred to as a second pad area PDA2) of the display panel 110. When viewed from the top (e.g., in a plan view), the second pad area PDA2 may include, for example, an area where the first connection circuit board CB1 and the control circuit board CCB overlap each other. The second pad area PDA2 may be disposed in the non-display area NDA of the display panel 110.

The plurality of second pads PD2 of the display panel 110 may be connected to the opposite side of the first connection circuit board CB1, such as an upper side of the first connection circuit board CB1 in the second direction DR2.

In an embodiment, the plurality of second pads PD2 of the display panel 110 may include first sub-pads SPD11 and second sub-pads SPD22 arranged in different rows in the second pad area PDA2, such as first and second rows, respectively. The first row and the second row may be arranged along the second direction DR2.

In the second pad area PDA2, the first sub-pads SPD11 may be disposed on the upper side of the second sub-pads SPD22 (e.g., in the second direction DR2). For example, when viewed from the top, the first sub-pads SPD11 may be arranged in the second pad area PDA2 between the opposite side S2 of the first connection circuit board CB1 and the second sub-pads SPD22 (e.g., in the second direction DR2).

The first sub-pads SPD11 of the display panel 110 are identical to the above-described first sub-pads SPD1 of the control circuit board CCB of FIGS. 2, 3, 5, 6, 7, 8, 9 and 10; and, therefore, the redundant descriptions will be omitted.

The second sub-pads SPD22 of the display panel 110 are identical to the above-described second sub-pads SPD2 of the control circuit board CCB of FIGS. 2, 3, 5, 6, 7, 8, 9 and 10; and, therefore, the redundant descriptions will be omitted.

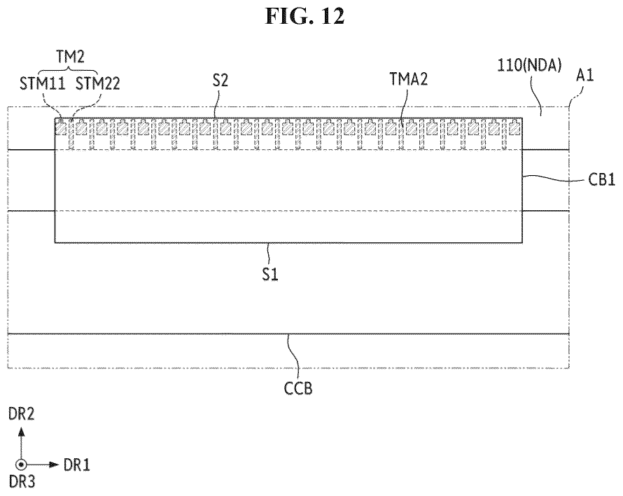

FIG. 12 is an enlarged view of area A1 of FIG. 1 for illustrating other terminals of the first connection circuit board CB1 of FIG. 1.

As shown in FIG. 12, the first connection circuit board CB1 may include a plurality of terminals TM2 (hereinafter referred to as second terminals TM2). A plurality of second terminals TM2 may be disposed in a terminal area TMA2 (hereinafter referred to as a second terminal area TMA2) of the first connection circuit board CB1. In an embodiment, the second terminal area TMA2 may be disposed on an upper side of the first connection circuit board CB1 in the second direction DR2. When viewed from the top, the second terminal area TMA2 may include, for example, an area where the first connection circuit board CB1 and the display panel 110 overlap each other.

The plurality of second terminals TM2 of the first connection circuit board CB1 may be connected to one side of the display panel 110. For example, the plurality of second terminals TM2 of the first connection circuit board CB1 may be connected to the second pads PD2 of the display panel 110, respectively. For example, the plurality of second terminals TM2 and the second pads PD2 may be electrically connected with each other directly or via connecting members such as conductive balls. In an embodiment, the connection members may include conductive adhesive members such as an anisotropic conductive film.

In an embodiment, the plurality of second terminals TM2 of the first connection circuit board CB1 may include first sub-terminals STM11 and second sub-terminals STM22 having different shapes from each other arranged in the second terminal area TMA2.

The first sub-terminals STM11 may be connected to the first sub-pads SPD11 described above, respectively. For example, the plurality of first sub-terminals STM11 and the first sub-pads SPD11 may be electrically connected with each other directly or via connection members such as conductive balls. In an embodiment, the connection members may include conductive adhesive members such as an anisotropic conductive film.

In the second terminal area TMA2, the second sub-terminals STM22 may be disposed between the first sub-terminals STM11 (e.g., in the first direction DR1). For example, when viewed from the top, each of the second sub-terminals STM22 may be disposed between every two first sub-terminals STM11 adjacent to each other in the first direction DR1 in the second terminal area TMA2.

The second sub-terminals STM22 may be connected to the second sub-pads SPD22 described above, respectively. For example, the plurality of second sub-terminals STM22 and the second sub-pads SPD22 may be electrically connected with each other directly or via connection members such as conductive balls. In an embodiment, the connection members may include conductive adhesive members such as an anisotropic conductive film.

The first sub-terminals STM11 arranged in the second terminal area TMA2 of the first connection circuit board CB1 are identical to the above-described first sub-terminals STM1 arranged in the first terminal area TMA1 of the first connection circuit board CB1 of FIGS. 4, 5, 6, 7, 8, 9 and 10; and, therefore, the redundant descriptions will be omitted.

The second sub-terminals STM22 arranged in the second terminal area TMA2 of the first connection circuit board CB1 are identical to the above-described second sub-terminals STM2 arranged in the first terminal area TMA1 of the first connection circuit board CB1 of FIGS. 4, 5, 6, 7, 8, 9 and 10; and, therefore, the redundant descriptions will be omitted.

In addition, the relationships (e.g., the arrangement relationship and the connection relationship) between the second terminals TM22 arranged in the second terminal area TMA2 of the first connection circuit board CB1 and the second pads PD22 arranged in the second pad area PDA2 of the display panel 110 are identical to the above-described relationships between the first terminals TM1 arranged in the first terminal area TMA1 of the first connection circuit board CB1 and the first pads PD1 arranged in the first pad area PDA1 of the control circuit board CCB; and, therefore, the redundant descriptions will be omitted.

According to an embodiment of the present disclosure, the second connection circuit board CB2 may include third terminals and fourth terminals, the control circuit board CCB may further include third pads connected to the third terminals of the second connection circuit board CB2, and the display panel 110 may further include fourth pads connected to the fourth terminals of the second connection circuit board CB2. The third terminals of the second connection circuit board CB2 may be identical to the above-described first terminals TM1 of the first connection circuit board CB1, the fourth terminals of the second connection circuit board CB2 may be identical to the above-described second terminals TM2 of the first connection circuit board CB1, the third pads of the control circuit board CCB may be identical to the above-described first pads PD1 of the control circuit board CCB, and the fourth pads of the display panel 110 may be identical to the above-described first pads PD1 of the display panel 110. Therefore, redundant descriptions will be omitted.

The display device according to the embodiment can be applied to various electronic devices. The electronic device according to one embodiment includes the display device described above and may further include modules or devices having additional functions in addition to the display device.

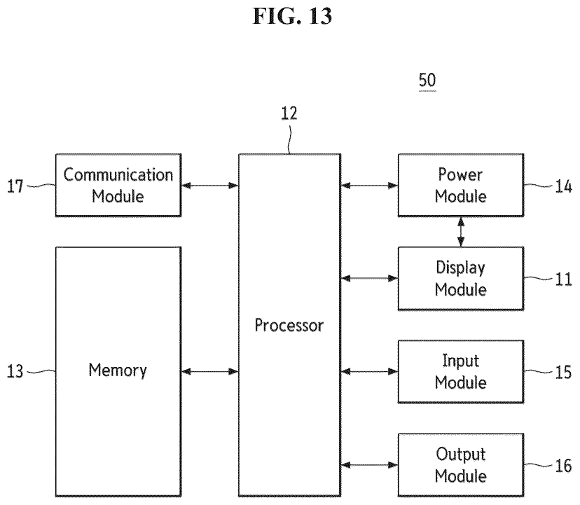

FIG. 13 is a block diagram of an electronic device according to one embodiment. Referring to FIG. 13, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

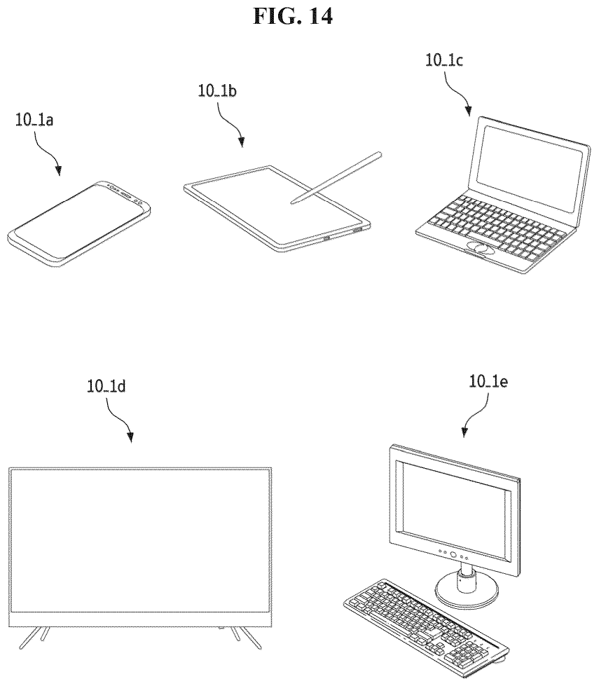

FIGS. 14, 15, and 16 are schematic diagrams of electronic devices according to various embodiments. FIGS. 14 to 16 illustrate examples of various electronic devices to which the display device according to the embodiments is applied.

FIG. 14 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

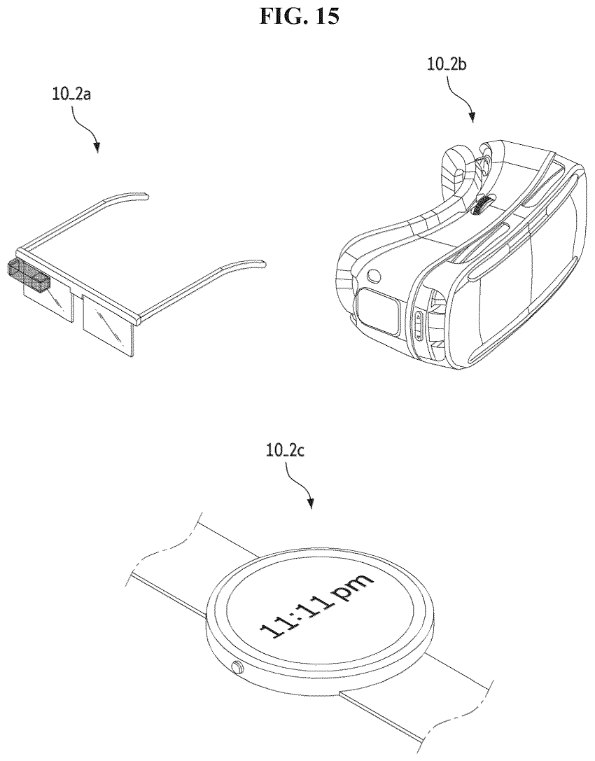

FIG. 15 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

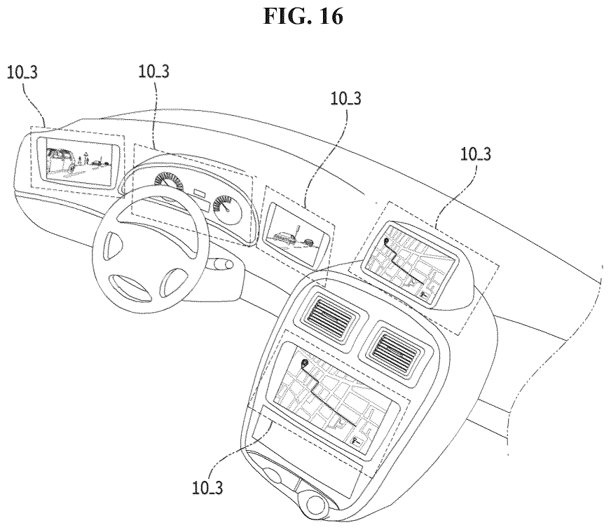

The smart watch 10_2c includes a biometric sensor as an input device, and may provide biometric information recognized by the biometric sensor to the user through the display module. FIG. 16 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the non-limiting embodiments described above are illustrative rather than being restrictive in all aspects. It is to be understood that the scope of embodiments of the present disclosure include all modifications and alterations and their equivalents.

What is claimed is:

1. A display device comprising:
a display panel;
a first circuit board connected to the display panel;
a second circuit board connected to the first circuit board;
a first pad disposed in a first pad area of the second circuit board; and
a first terminal disposed in a first terminal area of the first circuit board, the first terminal overlapping with the first pad in a plan view,
wherein the first pad comprises first sub-pads disposed in a first row of the first pad area and spaced apart from each other in a first direction and a second sub-pad disposed in a second row of the first pad area,
wherein the first terminal comprises first sub-terminals overlapping with the first sub-pads in the plan view and a second sub-terminal overlapping with the second sub-pad in the plan view, and
wherein the second sub-terminal is disposed between first sub-pads adjacent to each other in the first direction and extends longitudinally in a second direction intersecting the first direction to overlap with the second sub-pad in the plan view.

2. The display device of claim 1, wherein the first sub-pads and the second sub-pad extend longitudinally in different directions from each other.

3. The display device of claim 2, wherein the first sub-pads extend longitudinally in the second direction, and the second sub-pad extends longitudinally in the first direction.

4. The display device of claim 1, wherein the first sub-terminals comprise a first pattern portion and a second pattern portion having different widths in the first direction from each other.

5. The display device of claim 4, wherein the width of the first pattern portion in the first direction is greater than the width of the second pattern portion in the first direction.

6. The display device of claim 4, wherein the second pattern portion protrudes from an upper side of the first pattern portion in the second direction.

7. The display device of claim 1, wherein the first sub-terminals are disposed in the first terminal area and overlap with the first row of the first pad area in the plan view, and the second sub-terminal is disposed in the first terminal area and overlap with the first row and the second row of the first pad area in the plan view.

8. The display device of claim 1, wherein a width of the first sub-terminals in the first direction is greater than a width of the first sub-pads in the first direction.

9. The display device of claim 1, wherein a width of the second sub-pad in the first direction is greater than a width of the second sub-terminal in the first direction.

10. The display device of claim 1, further comprising:
a second pad disposed in a second pad area of the display panel; and
a second terminal disposed in a second terminal area of the first circuit board, the second terminal overlapping with the second pad in the plan view.

11. The display device of claim 10, wherein the second pad comprises: a third sub-pad disposed in a first row of the second pad area, and a fourth sub-pad disposed in a second row of the second pad area.

12. The display device of claim 11, wherein:
the second terminal comprises third sub-terminals overlapping with the third sub-pad and spaced apart from each other in the first direction and a fourth sub-terminal overlapping with the fourth sub-pad; and
the fourth sub-terminal is disposed between third sub-pads adjacent to each other in the first direction and extends longitudinally in the second direction to overlap with the fourth sub-pad in the plan view.

13. A display device comprising:
a display panel;
a first circuit board connected to the display panel;
a second circuit board connected to the first circuit board;
a first pad disposed in a first pad area of the display panel; and
a first terminal disposed in a first terminal area of the first circuit board, the first terminal overlapping with the first pad in a plan view,
wherein the first pad comprises first sub-pads disposed in a first row of the first pad area and spaced apart from each other in a first direction and a second sub-pad disposed in a second row of the first pad area,
wherein the first terminal comprises first sub-terminals overlapping with the first sub-pads in the plan view and a second sub-terminal overlapping with the second sub-pad in the plan view, and
wherein the second sub-terminal is disposed between first sub-pads adjacent to each other in the first direction and extends longitudinally in a second direction intersecting the first direction to overlap with the second sub-pad in the plan view.

14. The display device of claim 13, wherein the first sub-pads and the second sub-pad extend longitudinally in different directions.

15. The display device of claim 14, wherein the first sub-pads extend longitudinally in the second direction, and the second sub-pad extends longitudinally in the first direction.

16. The display device of claim 13, wherein the first sub-terminals comprise a first pattern portion and a second pattern portion having different widths in the first direction from each other.

17. The display device of claim 16, wherein the width of the first pattern portion in the first direction is greater than the width of the second pattern portion in the first direction.

18. The display device of claim 16, wherein the second pattern portion protrudes from an upper side of the first pattern portion in the second direction.

19. The display device of claim 13, wherein the first sub-terminals are disposed in the first terminal area and overlap with the first row of the first pad area in the plan view, and the second sub-terminal is disposed in the first terminal area and overlaps with the first row and the second row of the first pad area in the plan view.

20. An electronic device, comprising:
a display device; and
a power supply providing power to the display device,
wherein the display device comprises:
a display panel;
a first circuit board connected to the display panel;
a second circuit board connected to the first circuit board;
a first pad disposed in a first pad area of the second circuit board; and
a first terminal disposed in a first terminal area of the first circuit board, the first terminal overlapping with the first pad in a plan view,
wherein the first pad comprises first sub-pads disposed in a first row of the first pad area and spaced apart from each other in a first direction and second sub-pads disposed in a second row of the first pad area and spaced apart from each other in the first direction,
wherein the first terminal comprises first sub-terminals overlapping with the first sub-pads in the plan view and second sub-terminals overlapping with the second sub-pads in the plan view, and
wherein each of the second sub-terminals is disposed between adjacent first sub-pads that are adjacent to each other in the first direction and extend longitudinally in a second direction intersecting the first direction to overlap with one second sub-pad of the second sub-pads in the plan view.
